(19) United States
(12) Patent Application Publication
(10) Pub. No.: US 2026/0293272 A1
(43) Pub. Date: Sep. 24, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Yasutomo SAKURAI, Kawasaki Kanagawa (JP); Masahiro KOYAMA, Machida Tokyo (JP); Hitoshi IMI, Yokohama Kanagawa (JP); Shugo SUZUKI, Hanno Saitama (JP)

(21) Appl. No.: 19/351,962

(22) Filed: Oct. 7, 2025

(30) Foreign Application Priority Data
Mar. 19, 2025 (JP) 2025-045786

(51) Int. Cl. H10D 80/20; H10W 70/40; H10W 90/00

(52) U.S. Cl. CPC H10D 80/251; H10D 80/215; H10W 70/415; H10W 70/475; H10W 70/481; H10W 90/811

(57) ABSTRACT

According to one embodiment, a semiconductor device includes a first terminal to which a first voltage is applied, a second terminal to which a second voltage is applied, a third terminal to which a third voltage is applied, a first node, a second node, a fourth terminal which is coupled to the second node and to which a fourth voltage is applied, a first switch, a second switch, a third switch, and a fourth switch. The first switch is a normally-on type switch coupled between the second terminal and the first node. The second switch is a normally-on type switch coupled between the first node and the second node. The third switch is a normally-off type switch coupled between the first node and the first terminal. The fourth switch is a normally-off type switch coupled between the second node and the third terminal.

### CROSS-REFERENCE TO RELATED APPLICATIONS

This application is based upon and claims the benefit of priority from Japanese Patent Application No. 2025-045786, filed March 19, 2025, the entire contents of which are incorporated herein by reference.

### FIELD

Embodiments described herein relate generally to a semiconductor device.

### BACKGROUND

A semiconductor device configured to perform power conversion and control is known.

### BRIEF DESCRIPTION OF THE DRAWINGS

FIG. 1 is a circuit diagram showing an example of a circuit configuration of a semiconductor device according to a first embodiment.

FIG. 2 is a circuit diagram showing an example of a configuration of each switching element in the semiconductor device according to the first embodiment.

FIG. 3 is a perspective view showing an example of the structure of the semiconductor device according to the first embodiment.

FIG. 4 is a cross-sectional view showing an example of a cross-sectional structure of the semiconductor device according to the first embodiment.

FIG. 5 is a diagram showing a high-frequency current path of the semiconductor device according to the first embodiment.

FIG. 6 is a perspective view showing an example of a structure of a semiconductor device according to a second embodiment.

FIG. 7 is a diagram showing a high-frequency current path of the semiconductor device according to the second embodiment.

FIG. 8 is a cross-sectional view showing an example of a cross-sectional structure of a semiconductor device according to a third embodiment.

FIG. 9 is a diagram showing a high-frequency current path of the semiconductor device according to the third embodiment.

FIG. 10 is a cross-sectional view showing an example of a cross-sectional structure of a semiconductor device according to a fourth embodiment.

FIG. 11 is a diagram showing a high-frequency current path of the semiconductor device according to the fourth embodiment.

FIG. 12 is a circuit diagram showing an example of a circuit configuration of a semiconductor device according to a fifth embodiment.

FIG. 13 is a circuit diagram showing an example of a configuration of each switching element in the semiconductor device according to the fifth embodiment.

FIG. 14 is a cross-sectional view showing an example of a cross-sectional structure of the semiconductor device according to the fifth embodiment.

FIG. 15 is a diagram showing a high-frequency current path of a power supply module including the semiconductor device according to the fifth embodiment.

FIG. 16 is a cross-sectional view showing an example of a cross-sectional structure of a semiconductor device according a modification of the third embodiment.

FIG. 17 is a cross-sectional view showing an example of a cross-sectional structure of a semiconductor device according to a modification of the fourth embodiment.

### DETAILED DESCRIPTION

In general, according to one embodiment, a semiconductor device includes a first terminal to which a first voltage is applied, a second terminal to which a second voltage higher than the first voltage is applied, a third terminal to which a third voltage lower than the first voltage is applied, a first node, a second node, a fourth terminal which is coupled to the second node and to which a fourth voltage lower than the first voltage is applied, a first switch, a second switch, a third switch, and a fourth switch. The first switch is a normally-on type switch coupled between the second terminal and the first node. The second switch is a normally-on type switch coupled between the first node and the second node. The third switch is a normally-off type switch coupled between the first node and the first terminal. The fourth switch is a normally-off type switch coupled between the second node and the third terminal.

Hereinafter, an embodiment will be described with reference to the accompanying drawings. The dimensions and ratios in the drawings are not always the same as the actual ones. In the following description, constituent elements having substantially the same function and configuration will be assigned the same reference symbol, and repeat descriptions may be omitted. In a case where elements having similar configurations are distinguished from each other in particular, letters or numbers different from each other may be added to the end of the same reference symbol. All of the descriptions of an embodiment are applicable as descriptions of another embodiment, unless explicitly or self-evidently excluded.

### 1. First Embodiment

A semiconductor device according to a first embodiment will be described. The following description will discuss, as an example, a semiconductor device configured to perform power conversion and control by alternately driving a switching element at a High side and a switching element at a Low side. The semiconductor device according to the present embodiment is applied to, for example, an AC-DC converter, a DC-AC inverter, a DC-DC converter, etc.

### 1.1 Circuit Configuration of Semiconductor Device

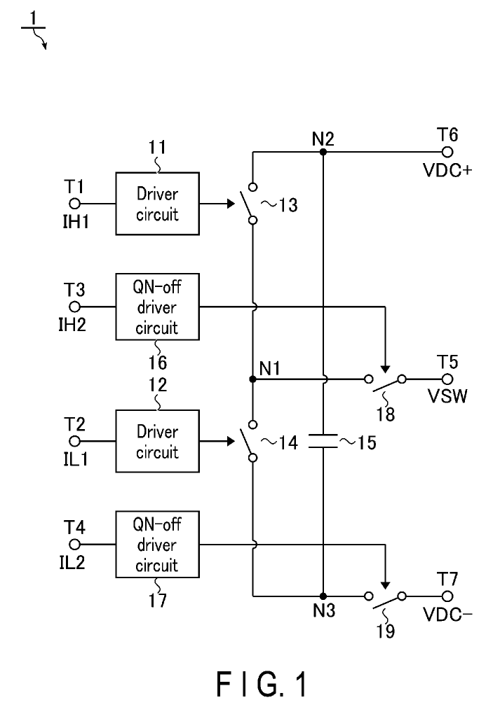

A circuit configuration of the semiconductor device will be described with reference to FIG. 1. FIG. 1 is a circuit diagram showing an example of the circuit configuration of the semiconductor device.

A semiconductor device 1 is, for example, a power supply module. As shown in FIG. 1, the semiconductor device 1 includes control terminals T1 and T2, driver circuits 11 and 12, input/output terminals T5 to T7, switching elements (hereinafter, also referred to as “switches”) 13 and 14, a capacitor 15, control terminals T3 and T4, QN-off driver circuits 16 and 17, and switching elements (hereinafter, also referred to as “switches”) 18 and 19.

A control terminal T1 is a terminal to which a control signal IH1 is input from outside. The control signal IH1 is a signal for controlling an operation of the driver circuit 11. The control signal IH1 is, for example, either a signal at a High (“H”) level or a signal at a Low (“L”) level.

A control terminal T2 is a terminal to which a control signal IL1 is input from outside. The control signal IL1 is a signal for controlling an operation of the driver circuit 12. The control signal IL1 is, for example, either a signal at the “H” level or a signal at the “L” level.

The driver circuit 11 is a circuit configured to drive the switching element 13. The driver circuit 11 is coupled to the control terminal T1 and the switching element 13. The driver circuit 11 is configured to turn on or turn off the switching element 13 on the basis of the control signal IH1. For example, the driver circuit 11 is configured to turn on the switching element 13 in accordance with an ON request signal directed to the switching element 13 by the control signal IH1. The driver circuit 11 is configured to turn off the switching element 13 in accordance with an OFF request signal directed to the switching element 13 by the control signal IH1.

The driver circuit 12 is a circuit configured to drive the switch element 14. The driver circuit 12 is coupled to the control terminal T2 and the switch element 14. The driver circuit 12 is configured to turn on or turn off the switching element 14 on the basis of the control signal IL1. For example, the driver circuit 12 is configured to turn on the switching element 14 in accordance with an ON request signal directed to the switching element 14 by the control signal IL1. The driver circuit 12 is configured to turn off the switching element 14 in accordance with an OFF request signal directed to the switching element 14 by the control signal IL1.

The input/output terminals T5 to T7 are each an input terminal or an output terminal. The input/output terminal T5 is coupled to a node N1 via the switching element 18. The input/output terminal T6 is coupled to a node N2. The input/output terminal T7 is coupled to a node N3 via the switching element 19. A voltage VDC- is a DC voltage to be applied to the input/output terminal T7. The voltage VDC- is applied to the node N3 via the switching element 19. The voltage VDC- is, for example, a ground voltage. A voltage VDC+ is a DC voltage to be applied to the input/output terminal T6. The voltage VDC+ is applied to the node N2. The voltage VDC+ is a voltage higher than the voltage VDC-. A voltage VSW is a DC voltage to be applied to the input/output terminal T5. The voltage VSW is applied to the node N1 via the switching element 18. The voltage VSW is switched between the voltage VDC- and the voltage VDC+. The voltage VSW may exceed the voltage VDC+ due to a surge caused by a parasitic inductance of interconnect at the time of switching of the switching elements 13 and 14. The voltage VSW is a voltage that is higher than the voltage VDC- and is lower than the voltage VDC+ in a steady state. In other words, the voltage VDC+ is a voltage higher than the voltage VSW, and the voltage VDC- is a voltage lower than the voltage VSW.

The switching element 13 has a first end, a second end, and a third end. The first end of the switching element 13 is coupled to the driver circuit 11. The second end of the switching element 13 is coupled to the node N2. The third end of the switching element 13 is coupled to the node N1. In other words, the switching element 13 is coupled between the input/output terminal T6 and the node N1.

The switching element 14 has a first end, a second end, and a third end. The first end of the switching element 14 is coupled to the driver circuit 12. The second end of the switching element 14 is coupled to the node N1. The third end of the switching element 14 is coupled to the node N3. In other words, the switching element 14 is coupled between the node N1 and the node N3.

The switching elements 13 and 14 each include, for example, at least one of an n-channel metal-oxide-semiconductor field-effect transistor (MOSFET), a p-channel MOSFET, a gallium nitride (GaN) transistor, a silicon carbide (SiC) transistor, an insulated-gate bipolar transistor (IGBT), and a junction field-effect transistor (JFET). Furthermore, the switching elements 13 and 14 are normally-on type switching elements.

One electrode of the capacitor 15 is coupled to the node N2. The other electrode of the capacitor 15 is coupled to the node N3. In other words, the capacitor 15 is coupled between the input/output terminal T6 and the node N3. That is, the capacitor 15 is coupled to both ends of the switching elements 13 and 14 coupled in series. As a result, the capacitor 15 functions as a snubber capacitor for reducing a surge that may be caused by a parasitic inductance of an interconnect at the time of switching between ON and OFF of the switching elements 13 and 14.

The control terminal T3 is a terminal to which the control signal IH2 is input from outside. The control signal IH2 is a signal for controlling an operation of the QN-off driver circuit 16. The control signal IH2 is, for example, either a signal at the “H” level or a signal at the “L” level.

A control terminal T4 is a terminal to which the control signal IL2 is input from outside. The control signal IL2 is a signal for controlling an operation of the QN-off driver circuit 17. The control signal IL2 is, for example, either a signal at the “H” level or a signal at the “L” level.

The QN-off driver circuits 16 and 17 are each a driver circuit for realizing a quasi-normally-off.

The QN-off driver circuit 16 is a circuit configured to drive the switching element 18. The QN-off driver circuit 16 is coupled to the control terminal T3 and the switching element 18. The QN-off driver circuit 16 is configured to turn on or turn off the switching element 18 on the basis of the control signal IH2.

The QN-off driver circuit 17 is a circuit configured to drive the switching element 19. The QN-off driver circuit 17 is coupled to the control terminal T4 and the switching element 19. The QN-off driver circuit 17 is configured to turn on turn or off the switching element 19 on the basis of the control signal IL2.

Meanwhile, in a case where the entire system including the semiconductor device 1 is powered on or off, that is, in a case where a power supply is in an unstable state, the switching elements 13 and 14 may be unintentionally turned on. Therefore, in a case where the power supply is in the unstable state, the control signals IH2 and IL2 are controlled in such a manner that the switching elements 18 and 19 are turned off. In this manner, the switching elements at the High side including the switching elements 13 and 18, and the switching elements at the Low side including the switching elements 14 and 19 are both turned to an OFF state. On the other hand, in a case where the power supply is in the steady state, the control signals IH2 and IL2 are controlled in such a manner that the switching elements 18 and 19 are turned on. The control signals IH1 and IL1 are controlled in such a manner that the switching elements 13 and 14 are alternately turned on or off. In this manner, the switching elements at the High side including the switching elements 13 and 18 and the switching elements at the Low side including the switching elements 14 and 19 are alternately turned to an ON state or an OFF state. In this manner, a “quasi-normally-off” is realized. Power conversion and control are performed by alternately driving the switching elements at the High side and the switching elements at the Low side.

The switching element 18 has a first end, a second end, and a third end. The first end of the switching element 18 is coupled to the QN-off driver circuit 16. The second end of the switching element 18 is coupled to the node N1. The third end of the switching element 18 is coupled to the input/output terminal T5. In other words, the switching element 18 is coupled between the node N1 and the input/output terminal T5.

The switching element 19 has a first end, a second end, and a third end. The first end of the switching element 19 is coupled to the QN-off driver circuit 17. The second end of the switching element 19 is coupled to the node N3. The third end of the switching element 19 is coupled to the input/output terminal T7. In other words, the switching element 19 is coupled between the node N3 and the input/output terminal T7.

The switching elements 18 and 19 include at least one of the n-channel MOSFET and the p-channel MOSFET. Furthermore, the switching elements 18 and 19 are normally-on type switching elements.

The input/output terminals T5 to T7 each serve as an input terminal or an output terminal depending on the configuration of each circuit (not shown) coupled thereto.

For example, in a case where the semiconductor device 1 and circuits coupled to the input/output terminals T5 to T7 form a synchronous rectification boost converter, the input/output terminal T5 serves as an input terminal, and the input/output terminals T6 and T7 serve as output terminals.

Furthermore, for example, in a case where the semiconductor device 1 and the circuits coupled to the input/output terminals T5 to T7 form a half-bridge converter, a full-bridge converter, a half-bridge LLC converter, a phase shift full-bridge converter, etc., the input/output terminal T5 serves as an output terminal, and the input/output terminals T6 and T7 serve as input terminals. In a case where the semiconductor device 1 and the circuits coupled to the input/output terminals T5 to T7 form a DC-AC inverter, the input/output terminal T5 also serves as an output terminal, and the input/output terminals T6 and T7 also serve as input terminals.

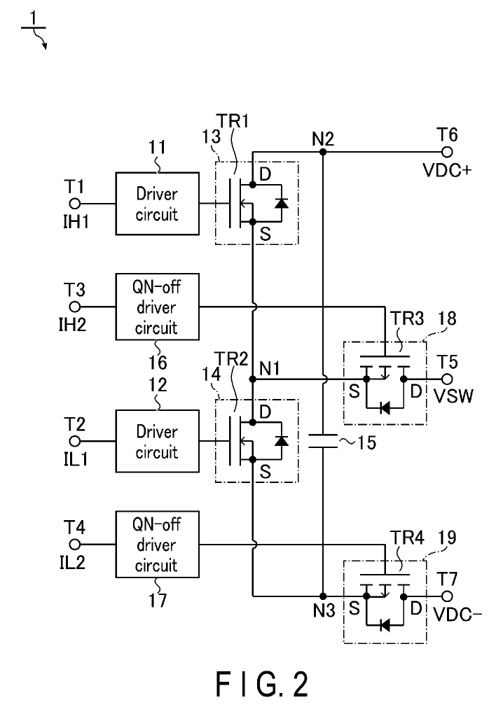

FIG. 2 is a circuit diagram showing an example of a configuration of each switching element in the semiconductor device 1.

As shown in FIG. 2, the switching element 13 is a transistor TR1. The switching element 14 is a transistor TR2. The transistors TR1 and TR2 are, for example, n-channel MOSFETs. Furthermore, the transistors TR1 and TR2 are normally-on type transistors.

A gate electrode (control electrode) of the switching element 13 is coupled to the driver circuit 11. A drain electrode of the switching element 13 is coupled to the node N2. In other words, the drain electrode of the switching element 13 is coupled to the input/output terminal T6. A source electrode of the switching element 13 is coupled to the node N1. A gate electrode of the switching element 14 is coupled to the driver circuit 12. A drain electrode of the switching element 14 is coupled to the node N1. A source electrode of the switching element 14 is coupled to the node N3. A source electrode of the switching element 13 is coupled to the drain electrode of the switching element 14. That is, the switching element 13 is coupled in series to the switching element 14.

The switching element 18 is a transistor TR3. The switching element 19 is a transistor TR4. The transistors TR3 and TR4 are, for example, p-channel MOSFETs. Furthermore, the transistors TR3 and TR4 are normally-off type transistors. Meanwhile, the transistors TR3 and TR4 may be n-channel MOSFETs. In a case where the transistors TR3 and TR4 are n-channel MOSFETs, in the following description, a drain electrode DE3 will be replaced with a source electrode SE3, and a drain electrode DE4 will be replaced with a source electrode SE4.

A gate electrode (control electrode) of the switching element 18 is coupled to the QN-off driver circuit 16. A source electrode of the switching element 18 is coupled to the node N1. A drain electrode of the switching element 18 is coupled to the input/output terminal T5. A gate electrode of the switching element 19 is coupled to the QN-off driver circuit 17. A source electrode of the switching element 19 is coupled to the node N3. A drain electrode of the switching element 19 is coupled to the input/output terminal T7. The source electrode of the switching element 18 is coupled to the source electrode of the switching element 13 and the drain electrode of the switching element 14. That is, the switching element 18 is coupled in parallel to the switching elements 13 and 14. The source electrode of the switching element 19 is coupled to the source electrode of the switching element 14. That is, the switching element 19 is coupled in series to the switching element 14.

### 1.2 Structure of Semiconductor Device

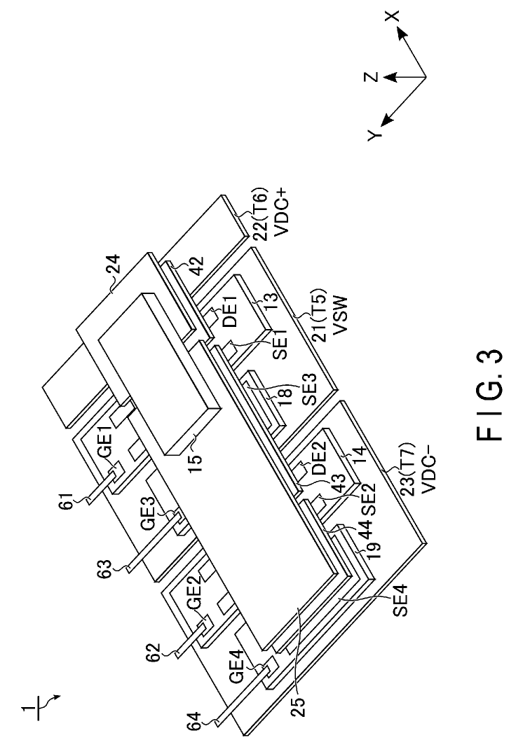

The structure of the semiconductor device 1 will be described with reference to FIG. 3. In the semiconductor device 1, a first substrate 51 to be described later is used. FIG. 3 is a perspective view showing an example of a structure of the semiconductor device 1.

As shown in FIG. 3, the semiconductor device 1 includes interconnect layers 21-25 and 42-44, switching elements 13, 14, 18, and 19, a capacitor 15, and interconnects 61 to 64. FIG. 3 omits illustration of the control terminals T1 to T4, the driver circuits 11 and 12, the QN-off driver circuits 16 and 17, a plurality of vias 41 to be described later, and the first substrate 51.

Hereinafter, a plane parallel to a plane of the interconnect layer 21 will be referred to as an “XY surface”. On the XY plane, directions perpendicularly intersecting each other will be referred to as an “X direction” and a “Y direction”. A direction intersecting the XY plane will be referred to as a Z direction. In the Z direction, a direction extending from the interconnect layer 21 to the switching element 13 will also be referred to as an “upper direction”, and a direction extending from the interconnect layer 21 to the side opposite to the switching element 13 will also be referred to as a “lower direction”. Throughout the specification, a plane in the upper direction of each of the interconnect layers, the switching elements, and the substrate will be referred to as an “upper surface” or “front surface”, and a plane in the lower direction of each of the interconnect layers, the switching elements, and the substrate will be referred to as a “lower surface” or “back surface”.

The interconnect layers 21 to 23 are arranged apart from each other in the X direction. The interconnect layer 21 is arranged between the interconnect layer 22 and the interconnect layer 23 in the X direction. The interconnect layer 21 corresponds to the input/output terminal T5. Hereinafter, the interconnect layer 21 will also be referred to as the “input/output terminal T5”. The voltage VSW is applied to the interconnect layer 21. The interconnect layer 22 corresponds to the input/output terminal T6. Hereinafter, the interconnect layer 22 will also be referred to as the “input/output terminal T6”. The voltage VDC+ is applied to the interconnect layer 22. The interconnect layer 23 corresponds to the input/output terminal T7. Hereinafter, the interconnect layer 23 will also be referred to as the “input/output terminal T7”. The voltage VDC- is applied to the interconnect layer 23.

The switching elements 13 and 18 are provided above the interconnect layer 21. The switching elements 13 and 18 are arranged apart from each other in the X direction. The switching elements 13 and 18 are arranged in this order from the side of the interconnect layer 22 in the X direction.

A drain electrode DE1, a source electrode SE1, and a gate electrode GE1 are provided inside the switching element 13 and are in contact with the front surface of the switching element 13. The drain electrode DE1 is provided on an end portion of the front surface of the switching element 13, the end portion being closer to the interconnect layer 22. The source electrode SE1 and the gate electrode GE1 are provided on an end portion of the front surface of the switching element 13, the end portion being closer to the switching element 18. In other words, the drain electrode DE1 and a pair of the source electrode SE1 and the gate electrode GE1 are arranged apart from each other in the X direction. The gate electrode GE1 is provided on one of the end portions in the Y direction of the front surface of the switching element 13. The source electrode SE1 and the gate electrode GE1 are arranged apart from each other in the Y direction.

A source electrode SE3 and a gate electrode GE3 are provided inside the switching element 18 and are in contact with the front surface of the switching element 18. The gate electrode GE3 is provided on one of the end portions in the Y direction of the front surface of the switching element 18. The source electrode SE3 and the gate electrode GE3 are arranged apart from each other in the Y direction. A drain electrode DE3 (not shown) is provided inside the switching element 18 and is in contact with the back surface of the switching element 18.

The switching elements 14 and 19 are provided above the interconnect layer 23. The switching elements 14 and 19 are arranged apart from each other in the X direction. The switching elements 14 and 19 are arranged in this order from the side of the interconnect layer 21 in the X direction.

A drain electrode DE2, a source electrode SE2, and a gate electrode GE2 are provided inside the switching element 14 and are in contact with the front surface of the switching element 14. The drain electrode DE2 is provided on an end portion of the front surface of the switching element 14, the end portion being closer to the interconnect layer 21. The source electrode SE2 and the gate electrode GE2 are provided on an end portion of the front surface of the switching element 14, the end portion being closer to the switching element 19. In other word, the drain electrode DE2 and a pair of the source electrode SE2 and the gate electrode GE2 are arranged apart from each other in the X direction. The gate electrode GE2 is provided on one of the end portions in the Y direction of the front surface of the switching element 14. The source electrode SE2 and the gate electrode GE2 are arranged apart from each other in the Y direction.

A source electrode SE4 and a gate electrode GE4 are provided inside the switching element 19 and are in contact with the front surface of the switching element 19. The gate electrode GE4 is provided on one of the end portions in the Y direction of the front surface of the switching element 19. The source electrode SE4 and the gate electrode GE4 are arranged apart from each other in the Y direction. A drain electrode DE4 (not shown) is provided inside the switching element 19 and is in contact with the back surface of the switching element 19.

The interconnect layer 42 is provided above the interconnect layer 22 and the switching element 13. The interconnect layer 43 is provided above the switching elements 13, 18, and 14. The interconnect layer 44 is provided above the switching elements 14 and 19. The interconnect layers 42 to 44 are arranged apart from each other in the X direction. The interconnect layer 43 is arranged between the interconnect layer 42 and the interconnect layer 44 in the X direction.

The interconnect layer 24 is provided above the interconnect layer 42. The interconnect layer 25 is provided above the interconnect layers 43 and 44.

The capacitor 15 is provided on the front surfaces of the interconnect layers 24 and 25.

The interconnect 61 is an interconnect for coupling the switching element 13 and the driver circuit 11 (not shown). The interconnect 61 extends in the Y direction. One end of the interconnect 61 is coupled to the gate electrode GE1 of the switching element 13. The other end of the interconnect 61 is coupled to the driver circuit 11. The switching element 13 and the driver circuit 11 are arranged apart from each other in the Y direction.

The interconnect 62 is an interconnect for coupling the switching element 14 and the driver circuit 12 (not shown). The interconnect 62 extends in the Y direction. One end of the interconnect 62 is coupled to the gate electrode GE2 of the switching element 14. The other end of the interconnect 62 is coupled to the driver circuit 12. The switching element 14 and the driver circuit 12 are arranged apart from each other in the Y direction.

The interconnect 63 is an interconnect for coupling the switching element 18 and the QN-off driver circuit 16 (not shown). The interconnect 63 extends in the Y direction. One end of the interconnect 63 is coupled to the gate electrode GE3 of the switching element 18. The other end of the interconnect 63 is coupled to the QN-off driver circuit 16. The switching element 18 and the QN-off driver circuit 16 are arranged apart from each other in the Y direction.

The interconnect 64 is an interconnect for coupling the switching element 19 and the QN-off driver circuit 17 (not shown). The interconnect 64 extends in the Y direction. One end of the interconnect 64 is coupled to the gate electrode GE4 of the switching element 19. The other end of the interconnect 64 is coupled to the QN-off driver circuit 17. The switching element 19 and the QN-off driver circuit 17 are arranged apart from each other in the Y direction.

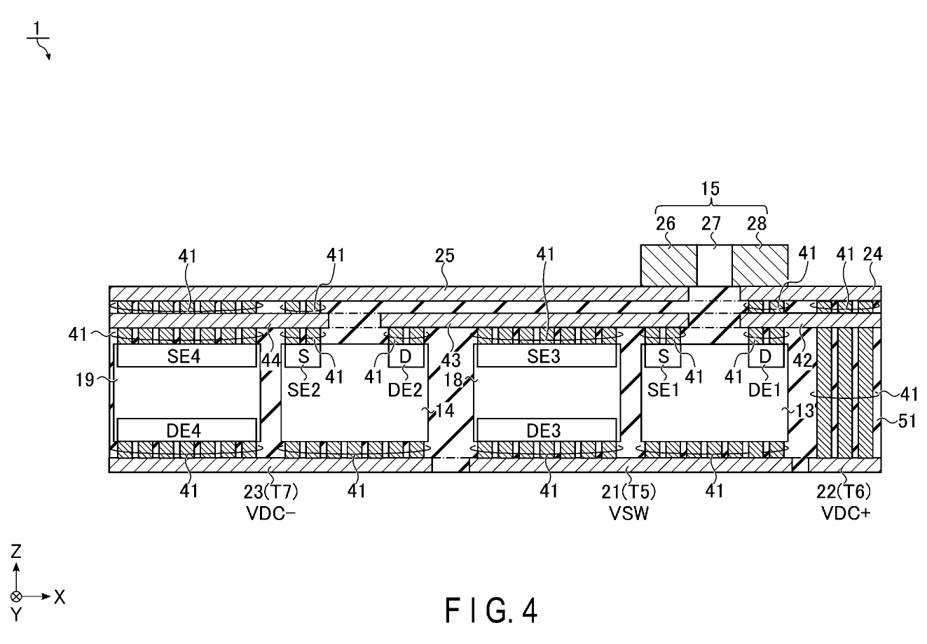

FIG. 4 is a cross-sectional view showing an example of the cross-sectional structure of the semiconductor device 1. FIG. 4 is a cross-sectional view along the XZ plane including the interconnect layers 21 to 25 and 42 to 44, the switching elements 13, 14, 18, and 19, the capacitor 15, and the first substrate 51.

As shown in FIG. 4, the first substrate 51 includes the switching elements 13, 14, 18, and 19, the interconnect layers 21 to 25 and 42 to 44, and the plurality of vias 41. Furthermore, although not shown in FIG. 4, the first substrate 51 includes the interconnects 61 to 64, the driver circuits 11 and 12, and the QN-off driver circuits 16 and 17. That is, the first substrate 51 is a component built-in substrate. The first substrate 51 is, for example, a glass epoxy substrate.

The interconnect layers 21 to 23 are provided inside the first substrate 51 and are in contact with the back surface of the first substrate 51. The interconnect layers 21 to 23 are provided in the same layer.

The switching elements 13 and 18 are provided above the interconnect layer 21. The switching element 13 is coupled to the interconnect layer 21 via the plurality of vias 41. The drain electrode DE3 of the switching element 18 is coupled to the interconnect layer 21 via the plurality of vias 41.

The switching elements 14 and 19 are provided above the interconnect layer 23. The switching element 14 is coupled to the interconnect layer 23 via the plurality of vias 41. The drain electrode DE4 of the switching element 19 is coupled to the interconnect layer 23 via the plurality of vias 41.

The interconnect layer 42 is provided above the interconnect layer 22 and the switching element 13. The interconnect layer 42 is coupled to the interconnect layer 22 via the plurality of vias 41. The interconnect layer 42 is coupled to the drain electrode DE1 of the switching element 13 via the plurality of vias 41.

The interconnect layer 43 is provided above the switching elements 13, 18, and 14. The interconnect layer 43 is coupled to the source electrode SE1 of the switching element 13 via the plurality of vias 41. The interconnect layer 43 is coupled to the source electrode SE3 of the switching element 18 via the plurality of vias 41. The interconnect layer 43 is coupled to the drain electrode DE2 of the switching element 14 via the plurality of vias 41. The interconnect layer 43 corresponds to the node N1. Hereinafter, the interconnect layer 43 will also be referred to as the “node N1”.

The interconnect layer 44 is provided above the switching elements 14 and 19. The interconnect layer 44 is coupled to the source electrode SE2 of the switching element 14 via the plurality of vias 41. The interconnect layer 44 is coupled to the source electrode SE4 of the switching element 19 via the plurality of vias 41. The interconnect layer 44 corresponds to the node N3. Hereinafter, the interconnect layer 44 will also be referred to as the “node N3”.

The interconnect layers 42 to 44 are provided in the same layer.

The interconnect layer 24 is provided above the interconnect layer 42. The interconnect layer 24 is coupled to the interconnect layer 42 via the plurality of vias 41. The plurality of vias 41 between the interconnect layer 24 and the interconnect layer 42 are respectively arranged in positions corresponding to, for example, the plurality of vias 41 between the interconnect layer 42 and the interconnect layer 22, and the plurality of vias 41 between the interconnect layer 42 and the drain electrode DE1 of the switching element 13.

The interconnect layer 25 is provided above the interconnect layers 43 and 44. The interconnect layer 25 is coupled to the interconnect layer 44 via the plurality of vias 41. The plurality of vias 41 between the interconnect layer 25 and the interconnect layer 44 are respectively arranged in positions corresponding to, for example, the plurality of vias 41 between the interconnect layer 44 and the source electrode SE2 of the switching element 14, and the plurality of vias 41 between the interconnect layer 44 and the source electrode SE4 of the switching element 19.

The interconnect layers 24 to 25 are provided inside the first substrate 51 and are in contact with the front surfaces of the first substrate 51. The interconnect layers 24 and 25 are provided in the same layer.

The capacitor 15 is provided on the front surfaces of the interconnect layers 24 and 25 and the front surface of the first substrate 51. The capacitor 15 includes an interconnect layer 26, a dielectric layer 27, and an interconnect layer 28. The dielectric layer 27 is arranged between the interconnect layer 26 and the interconnect layer 28 in the X direction. The interconnect layer 26 is provided on the front surface of the interconnect layer 25 and the front surface of the first substrate 51. The dielectric layer 27 is provided on the front surface of the first substrate 51. The interconnect layer 28 is provided on the front surface of the interconnect layers 24 and the front surface of the first substrate 51.

The interconnect layers 21 to 25, 26, 28, and 42 to 44 are formed of a conductive material. The interconnect layers 21 to 25, 26, 28, and 42 to 44 include, for example, copper (copper foil). Each via 41 is formed of a conductive material. The via 41 includes, for example, copper (copper plating). The dielectric layer 27 includes, for example, silicon or barium titanate. The dielectric layer 27 may include, for example, nitride.

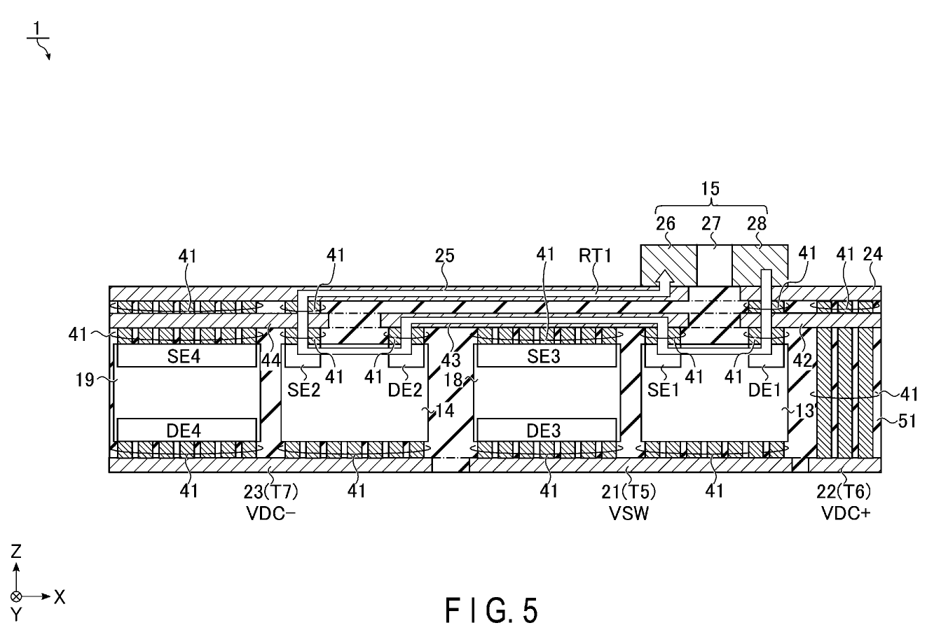

FIG. 5 is a diagram showing a high-frequency current path of the semiconductor device 1.

As shown in FIG. 5, a high-frequency current path RT1 of the semiconductor device 1 is a path starting from the interconnect layer 28, passing through the interconnect layer 24, the interconnect layer 42, the drain electrode DE1, the source electrode SE1, the interconnect layer 43, the drain electrode DE2, the source electrode SE2, the interconnect layer 44, and the interconnect layer 25, and reaching the interconnect layer 26.

As the number of switching elements, capacitors, etc., included in the high-frequency current path increases, this path is lengthened and the parasitic components (parasitic inductance and parasitic resistance) increases. An increase in parasitic components leads to an increase in noise and a decrease in power conversion efficiency due to the increase in noise. For this reason, it is necessary to minimize the parasitic components in the high-frequency current path.

The semiconductor device 1 according to the present embodiment has a circuit configuration shown in FIG. 1, so that the elements included in the high-frequency current path RT1 of the semiconductor device 1 are the switching elements 13 and 14 and the capacitor 15. For this reason, the high-frequency current path of the semiconductor device 1 is shorter than the high-frequency current path including another element or other elements in addition to the switching elements 13 and 14 and the capacitor 15. Accordingly, the semiconductor device 1 according to the present embodiment can reduce the parasitic components in the high-frequency current path.

The semiconductor device 1 according to the present embodiment has the structure shown in FIGS. 3 and FIG. 4.

Hereinafter, a semiconductor device having a configuration in which, in FIG. 1, the switching element 13, the switching element 18, the switching element 14, and the switching element 19 are coupled in series between the input/output terminals T6 and T7, and the input/output terminal T5 is coupled between the switching elements 18 and 14 will be referred to as a “semiconductor device according to a comparative example”.

The semiconductor device according to the comparative example assumes a case in which, for example, the interconnect layers 21 to 25 and 42 to 44 and the switching elements 13, 14, 18, and 19, and the capacitor 15 are arranged as in FIGS. 3 and FIG. 4. In such a case, it is necessary that a path from the interconnect layer 21 to the drain electrode DE2 of the switching element 14 be provided between the switching elements 18 and 14. Furthermore, it is necessary that a path from the interconnect layer 23 to the interconnect layer 25 be provided on the side opposite to the switching element 14 of the switching element 19.

The semiconductor device 1 according to the present embodiment does not need to be provided with the two paths described above in the semiconductor device according to the comparative example. For this reason, the semiconductor device 1 can reduce an area of a device as compared to the semiconductor device according to the comparative example. Therefore, the semiconductor device 1 according to the present embodiment can realize down-sizing of the device.

### 2. Second Embodiment

A semiconductor device according to a second embodiment will be described. A semiconductor device 1A according to the second embodiment differs from that of the first embodiment in terms of using a lead frame. A circuit configuration of the semiconductor device 1A according to the second embodiment is the same as that of the first embodiment. The following description will concentrate on the features different from the first embodiment.

### 2.1 Structure of Semiconductor Device

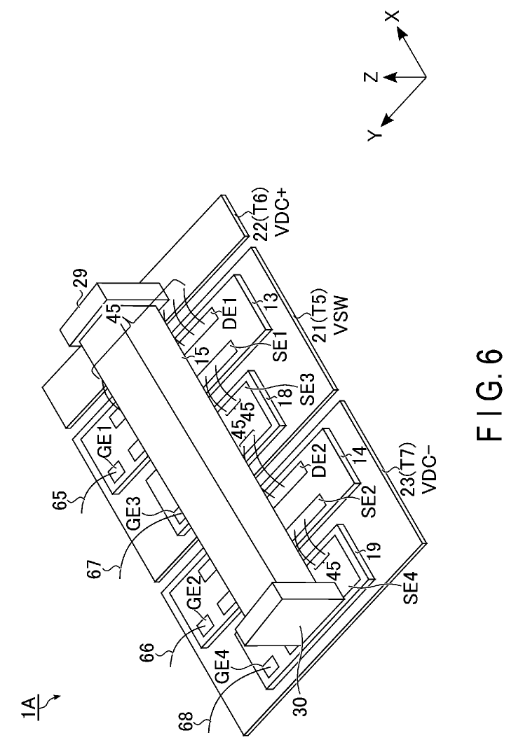

A structure of the semiconductor device 1A will be described with reference to FIG. 6. FIG. 6 is a perspective view showing an example of a structure of the semiconductor device 1A.

As shown in FIG. 6, the semiconductor device 1A includes the interconnect layers 21 to 23, 29, and 30, the switching elements 13, 14, 18, and 19, the capacitor 15, a plurality of bonding wires 45, and bonding wires 65 to 68. FIG. 6 omits illustration of the control terminals T1 to T4, the driver circuits 11 and 12, the QN-off driver circuits 16 and 17, and a sealing member to be described later, each included in the semiconductor device 1A.

The interconnect layers 21 to 23 are each a lead frame. The interconnect layers 21 to 23 are arranged apart from each other in the X direction. The interconnect layer 21 is arranged between the interconnect layer 22 and the interconnect layer 23 in the X direction. The interconnect layer 21 corresponds to the input/output terminal T5. The voltage VSW is applied to the interconnect layer 21. The interconnect layer 22 corresponds to the input/output terminal T6. The voltage VDC+ is applied to the interconnect layer 22. The interconnect layer 23 corresponds to the input/output terminal T7. The voltage VDC- is applied to the interconnect layer 23.

The switching elements 13 and 18 are provided on the front surface of the interconnect layer 21. The switching elements 13 and 18 are arranged apart from each other in the X direction. The switching elements 13 and 18 are arranged in this order from the side of the interconnect layer 22 in the X direction.

As with the first embodiment, the drain electrode DE1, the source electrode SE1, and the gate electrode GE1 are provided inside the switching element 13 and are in contact with the front surface of the switching element 13. The drain electrode DE1 of the switching element 13 is coupled to the interconnect layer 22 via the plurality of bonding wires 45.

The source electrode SE3 and the gate electrode GE3 are provided inside the switching element 18 and are in contact with the front surface of the switching element 18, as with the first embodiment. The drain electrode DE3 (not shown) is provided inside the switching element 18 and is in contact with the back surface of the switching element 18, as with the first embodiment. The source electrode SE3 of the switching element 18 is coupled to the source electrode SE1 of the switching element 13 via the plurality of bonding wires 45. The drain electrode DE3 of the switching element 18 is in contact with the interconnect layer 21. That is, the drain electrode DE3 of the switching element 18 is coupled to the interconnect layer 21.

The switching elements 14 and 19 are provided on the front surface of the interconnect layer 23.

The drain electrode DE2, the source electrode SE2, and the gate electrode GE2 are provided inside the switching element 14 and are in contact with the front surface of the switching element 14, as with the first embodiment. The drain electrode DE2 of the switching element 14 is coupled to the source electrode SE3 of the switching element 18 via the plurality of bonding wires 45.

The plurality of bonding wires 45 that couple the source electrode SE1 of the switching element 13 to the source electrode SE3 of the switching element 18, and the plurality of bonding wires 45 that couple the drain electrode DE2 of the switching element 14 to the source electrode SE3 of the switching element 18 correspond to the node N1.

The source electrode SE4 and the gate electrode GE4 are provided inside the switching element 19 and are in contact with the front surface of the switching element 19, as with the first embodiment. The drain electrode DE4 (not shown) is provided inside the switching element 19 and is in contact with the back surface of the switching element 19, as with the first embodiment. The source electrode SE4 of the switching element 19 is coupled to the source electrode SE2 of the switching element 14 via the plurality of bonding wires 45. The plurality of bonding wires 45 that couple the source electrode SE2 of the switching element 14 to the source electrode SE4 of the switching element 19 correspond to the node N3. The drain electrode DE4 of the switching element 19 is in contact with the interconnect layer 23. That is, the drain electrode DE4 of the switching element 19 is coupled to the interconnect layer 23.

The interconnect layer 29 is provided on the front surface of the interconnect layer 22.

The interconnect layer 30 is provided on the source electrode SE4 of the switching element 19.

The capacitor 15 is provided above the interconnect layers 21 to 23 and the switching elements 13, 14, 18, and 19. The capacitor 15 includes the interconnect layer 26, the dielectric layer 27, and the interconnect layer 28, as with the first embodiment. Both ends in the X direction of the capacitor 15 are in contact with the interconnect layers 29 and 30, respectively. That is, the interconnect layer 26 is in contact with the interconnect layer 30. The interconnect layer 28 is in contact with the interconnect layer 29.

The bonding wire 65 is an interconnect for coupling the switching element 13 to the driver circuit 11 (not shown). The bonding wire 65 extends in the Y direction. One end of the bonding wire 65 is coupled to the gate electrode GE1 of the switching element 13. The other end of the bonding wire 65 is coupled to the driver circuit 11. The switching element 13 and the driver circuit 11 are arranged apart from each other in the Y direction.

The bonding wire 66 is an interconnect for coupling the switching element 14 to the driver circuit 12 (not shown). The bonding wire 66 extends in the Y direction. One end of the bonding wire 66 is coupled to the gate electrode GE2 of the switching element 14. The other end of the bonding wire 66 is coupled to the driver circuit 12. The switching element 14 and the driver circuit 12 are arranged apart from each other in the Y direction.

The bonding wire 67 is an interconnect for coupling the switching element 18 to the QN-off driver circuit 16 (not shown). The bonding wire 67 extends in the Y direction. One end of the bonding wire 67 is coupled to the gate electrode GE3 of the switching element 18. The other end of the bonding wire 67 is coupled to the QN-off driver circuit 16. The switching element 18 and the QN-off driver circuit 16 are arranged apart from each other in the Y direction.

The bonding wire 68 is an interconnect for coupling the switching element 19 to the QN-off driver circuit 17 (not shown). The bonding wire 68 extends in the Y direction. One end of the bonding wire 68 is coupled to the gate electrode GE4 of the switching element 19. The other end of the bonding wire 68 is coupled to the QN-off driver circuit 17. The switching element 19 and the QN-off driver circuit 17 are arranged apart from each other in the Y direction.

The switching elements 13, 14, 18, and 19, the capacitor 15, the interconnect layers 29 and 30, the plurality of bonding wires 45, the bonding wires 65 to 68, the driver circuits 11 and 12, and the QN-off driver circuits 16 and 17 are covered with a sealing member (not shown). The sealing member includes, for example, insulating resin or ceramics, and polyimide.

The interconnect layers 21 to 23, 29, and 30 are formed of a conductive material. The interconnect layers 21 to 23, 29, and 30 include, for example, a metal material.

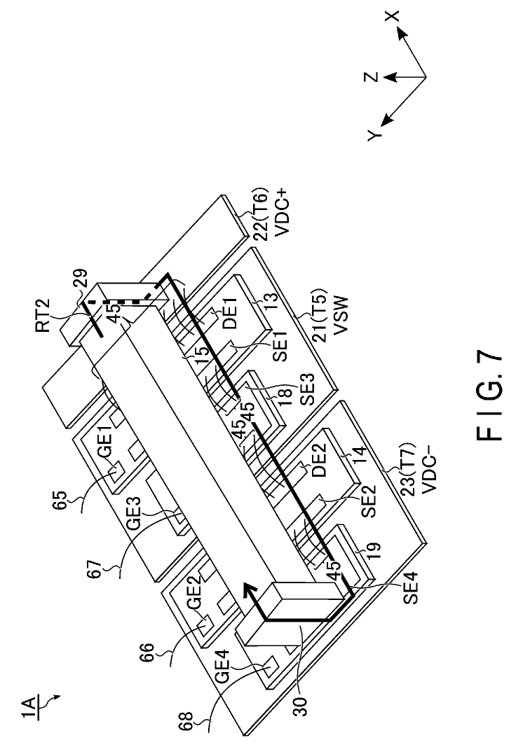

FIG. 7 is a view showing a high-frequency current path of the semiconductor device 1A.

As shown in FIG. 7, a high-frequency current path RT2 of the semiconductor device 1A is a path starting from the interconnect layer 28 (not shown) of the capacitor 15, passing through the interconnect layer 29, the interconnect layer 22, the drain electrode DE1, the source electrode SE1, the source electrode SE3, the drain electrode DE2, the source electrode SE2, the source electrode SE4, and the interconnect layer 30, and reaching the interconnect layer 26 (not shown) of the capacitor 15.

The semiconductor device 1A according to the present embodiment can reduce the parasitic components in the high-frequency current path as with the first embodiment.

The semiconductor device according to the comparative example described above assumes a case in which, for example, as in FIG. 6, the interconnect layers 21 to 23, the switching elements 13, 14, 18, and 19, and the plurality of bonding wires 45 are arranged, and the capacitor 15 is provided on the surfaces of the interconnect layers 22 and 23 extending in the Y direction further than the interconnect layer 21. In such a case, it is necessary that the switching elements 18 and 14 be coupled via the interconnect layer 21. Furthermore, it is necessary that the switching elements 19 and 15 be coupled via the interconnect layer 23.

In the semiconductor device 1A according to the present embodiment, the switching elements 18 and 14 can be coupled without the interconnect layer 21 intervening therebetween. The switching element 19 and the capacitor 15 can be coupled without the interconnect layer 23 intervening therebetween. Furthermore, direct coupling from the surface of the interconnect layer 21 and the surface of the switching element 19 to the capacitor 15 is achieved, so that the length of the interconnect layers 22 and 23 in the Y direction can be made relatively short. For this reason, the semiconductor device 1A can reduce an area of a device as compared to the semiconductor device according to the comparative example. Therefore, the semiconductor device 1A according to the present embodiment can realize down-sizing of the device.

### 3. Third Embodiment

A semiconductor device according to a third embodiment will be described. A semiconductor device 1B according to the third embodiment differs from that of the first embodiment in that the capacitor 15 is provided inside the first substrate 51. A circuit configuration of the semiconductor device 1B according to the third embodiment is the same as that of the first embodiment. The following description will concentrate on the features different from the first embodiment.

### 3.1 Structure of Semiconductor Device

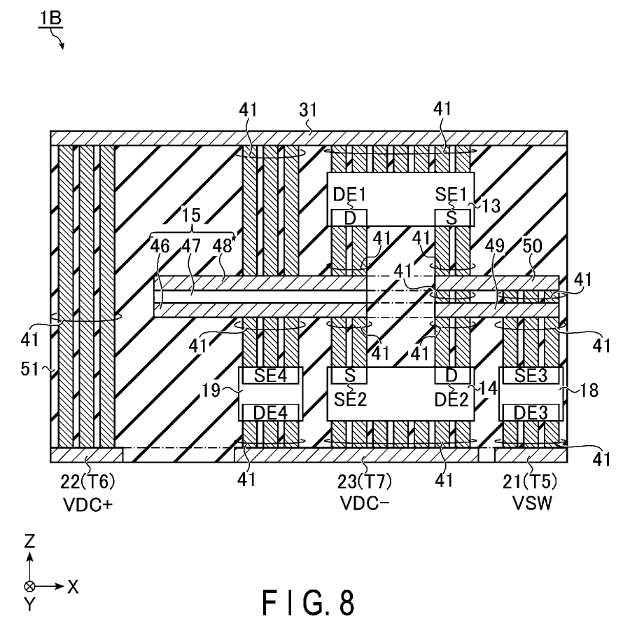

A structure of the semiconductor device 1B will be described with reference to FIG. 8. FIG. 8 is a cross-sectional view showing an example of the cross-sectional structure of the semiconductor device 1B. FIG. 8 is a cross-sectional view along the XZ plane including interconnect layers 21 to 23, 31, 49, and 50, the switching elements 13, 14, 18, and 19, the capacitor 15, the plurality of vias 41, and the first substrate 51.

As shown in FIG. 8, the first substrate 51 includes the interconnect layers 21 to 23, 49, and 50, the switching elements 13, 14, 18, and 19, the capacitor 15, and the plurality of vias 41. Furthermore, although not shown in FIG. 8, the first substrate 51 includes the interconnects 61 to 64, the driver circuits 11 and 12, and the QN-off driver circuits 16 and 17.

The interconnect layers 21 to 23 are provided inside the first substrate 51 and are in contact with the back surface of the first substrate 51. The interconnect layers 21 to 23 are arranged apart from each other in the X direction. The interconnect layer 23 is arranged between the interconnect layer 21 and the interconnect layer 22 in the X direction. The interconnect layers 21 to 23 are provided in the same layer.

The switching element 18 is provided above the interconnect layer 21.

The source electrode SE3 and the gate electrode GE3 (not shown) are provided inside the switching element 18 and are in contact with the front surface of the switching element 18, as with the first embodiment. The drain electrode DE3 is provided inside the switching element 18 and is in contact with the back surface of the switching element 18, as with the first embodiment. The drain electrode DE3 of the switching element 18 is coupled to the interconnect layer 21 via the plurality of vias 41.

The switching elements 14 and 19 are provided above the interconnect layer 23.

The drain electrode DE2, the source electrode SE2, and the gate electrode GE2 (not shown) are provided inside the switching element 14 and are in contact with the front surface of the switching element 14, as with the first embodiment. The back surface of the switching element 14 is coupled to the interconnect layer 23 via the plurality of vias 41.

The source electrode SE4 and the gate electrode GE4 (not shown) are provided inside the switching element 19 and are into contact with the front surface of the switching element 19, as with the first embodiment. The drain electrode DE4 is provided inside the switching element 19 and is in contact with the back surface of the switching element 19, as with the first embodiment. The drain electrode DE4 of the switching element 19 is coupled to the interconnect layer 23 via the plurality of vias 41.

The interconnect layer 49 is provided above the switching elements 18 and 14. The interconnect layer 49 is coupled to the source electrode SE3 of the switching element 18 via the plurality of vias 41. The interconnect layer 49 is coupled to the drain electrode DE2 of the switching element 14 via the plurality of vias 41. The interconnect layer 49 corresponds to the node N1. Hereinafter, the interconnect layer 49 will also be referred to as the “node N1”.

The interconnect layer 50 is provided above the interconnect layer 49. The interconnect layer 50 is coupled to the interconnect layer 49 via the plurality of vias 41. The plurality of vias 41 between the interconnect layer 50 and the interconnect layer 49 are respectively arranged in positions corresponding to, for example, the plurality of vias 41 between the interconnect layer 49 and the source electrode SE3 of the switching element 18, and the plurality of vias 41 between the interconnect layer 49 and the drain electrode DE2 of the switching element 14.

The capacitor 15 is provided above the switching elements 14 and 19. The capacitor 15 includes an interconnect layer 46, a dielectric layer 47, and an interconnect layer 48. The dielectric layer 47 is provided on a front surface of the interconnect layer 46. The interconnect layer 48 is provided on a front surface of the dielectric layer 47. The interconnect layer 46 is coupled to the source electrode SE2 of the switching element 14 via the plurality of vias 41. The interconnect layer 46 is coupled to the source electrode SE4 of the switching element 19 via the plurality of vias 41. The interconnect layers 46 and 49 are provided in the same layer. The interconnect layers 48 and 50 are provided in the same layer. The interconnect layer 46 is one electrode of the capacitor 15, and corresponds to the node N3. Hereinafter, the interconnect layer 46 will also be referred to as the “node N3”.

The switching element 13 is provided above the interconnect layers 50 and 48. In other words, the switching element 13 is provided above the interconnect layer 49 and the capacitor 15.

The drain electrode DE1, the source electrode SE1, and the gate electrode GE1 (not shown) are provided inside the switching element 13 and are in contact with the back surface of the switching element 13, as with the first embodiment. The source electrode SE1 of the switching element 13 is coupled to the interconnect layer 50 via the plurality of vias 41. The plurality of vias 41 between the source electrode SE1 of the switching element 13 and the interconnect layer 50 are respectively arranged in positions corresponding to, for example, the plurality of vias 41 between the interconnect layer 49 and the drain electrode DE2 of the switching element 14. The drain electrode DE1 of the switching element 13 is coupled to the interconnect layer 48 via the plurality of vias 41. The plurality of vias 41 between the drain electrode DE1 of the switching element 13 and the interconnect layer 48 are respectively arranged in positions corresponding to, for example, the plurality of vias 41 between the interconnect layer 46 and the source electrode SE2 of the switching element 14.

The interconnect layer 31 is provided above the interconnect layers 50, 48, and 22, and above the switching element 13. The interconnect layer 31 is provided inside the first substrate 51 and is in contact with the front surface of the first substrate 51. The front surface of the interconnect layer 48 is coupled to the interconnect layer 31 via the plurality of vias 41. The front surface of the interconnect layer 22 is coupled to the interconnect layer 31 via the plurality of vias 41. The front surface of the switching element 13 is coupled to the interconnect layer 31 via the plurality of vias 41.

The interconnect layers 31, 46, and 48 to 50 are formed of a conductive material. The interconnect layers 31, 46, and 48 to 50 include, for example, copper (copper foil). The dielectric layer 47 includes, for example, silicon or barium titanate. The dielectric layer 47 may include, for example, nitride.

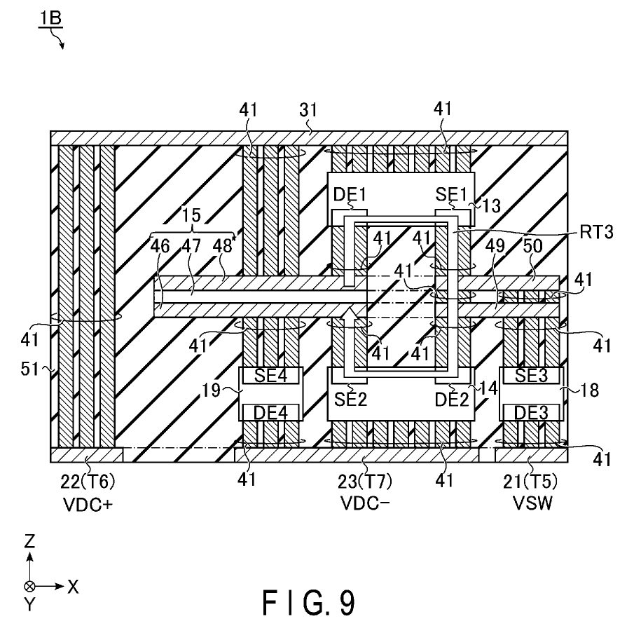

FIG. 9 is a view showing a high-frequency current path of the semiconductor device 1B.

As shown in FIG. 9, a high-frequency current path RT3 of the semiconductor device 1B is a path starting from the interconnect layer 48, passing through the drain electrode DE1, the source electrode SE1, the interconnect layer 50, the interconnect layer 49, the drain electrode DE2, and the source electrode SE2, and reaching the interconnect layer 46.

The semiconductor device 1B according to the present embodiment can reduce the parasitic components in the high-frequency current path as with the first embodiment.

The semiconductor device 1B according to the present embodiment has a structure in which, as shown in FIG. 8, each component built in the first substrate 51 is constituted of three layers (a layer including the switching elements 18, 14, and 19, a layer including the capacitor 15, and a layer including the switching element 13). For this reason, in the semiconductor device 1B, the first substrate 51 can be made relatively thin. Therefore, the semiconductor device 1B according to the present embodiment can realize film-thinning of the device.

Furthermore, the semiconductor device 1B according to the present embodiment has a structure in which the switching elements 13 and 14 are stacked and arranged in the Z direction, as shown in FIG. 8. Therefore, in the semiconductor device 1B, an area in the XY plane can be made relatively small. Therefore, the semiconductor device 1B according to the present embodiment can realize down-sizing of the device.

### 4. Fourth Embodiment

A semiconductor device according to a fourth embodiment will be described. A semiconductor device 1C according to the fourth embodiment differs from that of the third embodiment in that the interconnect layer 31 is eliminated, the interconnect layer 48 is longer than the interconnect layer 46 in the X direction, and the switching element 13 is provided on the front surface of the first substrate 51. A circuit configuration of the semiconductor device 1C according to the fourth embodiment is the same as that of the third embodiment. The following description will concentrate on the features different from the third embodiment.

### 4.1 Structure of Semiconductor Device

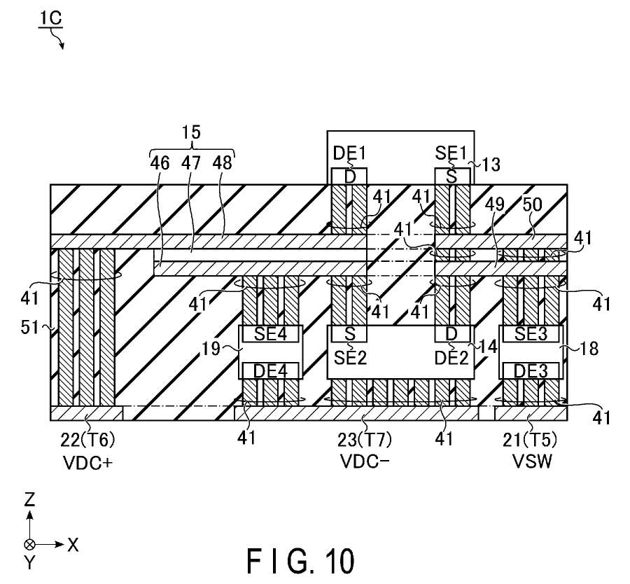

A structure of the semiconductor device 1C will be described with reference to FIG. 10. FIG. 10 is a cross-sectional view showing an example of the cross-sectional structure of the semiconductor device 1C. FIG. 10 is a cross-sectional view along the XZ plane including the interconnect layers 21 to 23, the switching elements 13, 14, 18, and 19, the capacitor 15, the plurality of vias 41, and the first substrate 51.

As shown in FIG. 10, the first substrate 51 includes the interconnect layers 21 to 23, 49, and 50, the switching elements 14, 18, and 19, the capacitor 15, and the plurality of vias 41. Furthermore, although not shown in FIG. 10, the first substrate 51 includes the interconnects 61 to 64, the driver circuits 11 and 12, and the QN-off driver circuits 16 and 17.

The interconnect layer 48 is longer than the interconnect layer 46 in the X direction. In other words, the interconnect layer 48 has a portion (hereinafter also referred to as an “extending portion”) that extends in the X direction further than the interconnect layer 46. The extending portion of the interconnect layer 48 is coupled to the interconnect layer 22 via the plurality of vias 41.

The switching element 13 is provided on the front surface of the first substrate 51. The switching element 13 is flip-chip mounted on the front surface of the first substrate 51.

The drain electrode DE1, the source electrode SE1, and the gate electrode GE1 (not shown) are provided inside the switching element 13 and are in contact with the back surface of the switching element 13, as with the first embodiment. The source electrode SE1 of the switching element 13 is coupled to the interconnect layer 50 via the plurality of vias 41. The plurality of vias 41 between the source electrode SE1 of the switching element 13 and the interconnect layer 50 are respectively arranged in positions corresponding to, for example, the plurality of vias 41 between the interconnect layer 49 and the drain electrode DE2 of the switching element 14. The drain electrode DE1 of the switching element 13 is coupled to the interconnect layer 48 via the plurality of vias 41. The plurality of vias 41 between the drain electrode DE1 of the switching element 13 and the interconnect layer 48 are respectively arranged in positions corresponding to, for example, the plurality of vias 41 between the interconnect layer 46 and the source electrode SE2 of the switching element 14.

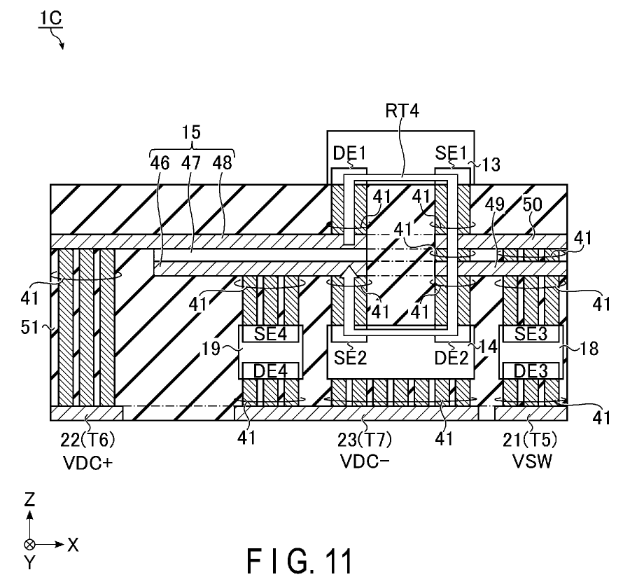

FIG. 11 is a view showing a high-frequency current path of the semiconductor device 1C.

As shown in FIG. 11, a high-frequency current path RT4 of the semiconductor device 1C is a path starting from the interconnect layer 48, passing through the drain electrode DE1, the source electrode SE1, the interconnect layer 50, the interconnect layer 49, the drain electrode DE2, and the source electrode SE2, and reaching the interconnect layer 46.

The semiconductor device 1C according to the present embodiment can reduce the parasitic components in the high-frequency current path as with the first embodiment.

The semiconductor device 1C according to the present embodiment has a structure in which, as shown in FIG. 10, each component built in the first substrate 51 is constituted of two layers (a layer including the switching elements 18, 14, and 19, and a layer including the capacitor 15). Therefore, in the semiconductor device 1C, the first substrate 51 can be made relatively thin. Therefore, the semiconductor device 1C according to the present embodiment can realize film-thinning of the device.

Furthermore, the semiconductor device 1C according to the present embodiment has a structure in which the switching elements 13 and 14 are stacked and arranged in the Z direction, as shown in FIG. 10. Therefore, in the semiconductor device 1C, an area in the XY plane can be made relatively small. Therefore, the semiconductor device 1C according to the present embodiment can realize down-sizing of the device.

### 5. Fifth Embodiment

A semiconductor device according to a fifth embodiment will be described. A semiconductor device 1D according to the fifth embodiment differs from that of the first embodiment in that the capacitor 15 is eliminated from the semiconductor device 1 and the input/output terminal T8 is added to the semiconductor device 1. The following description will concentrate on the features different from the first embodiment.

### 5.1 Circuit Configuration of Semiconductor Device

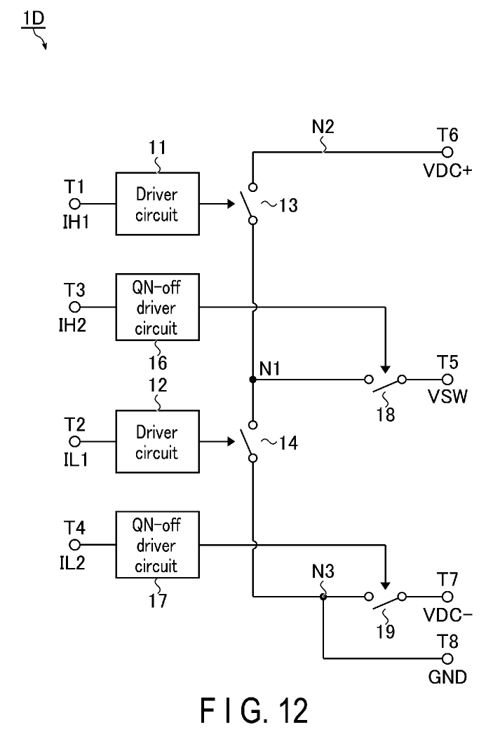

A circuit configuration of the semiconductor device 1D will be described with reference to FIG. 12. FIG. 12 is a circuit diagram showing an example of the circuit configuration of the semiconductor device 1D.

As shown in FIG. 12, the semiconductor device 1D includes the control terminals T1 and T2, the driver circuits 11 and 12, the input/output terminals T5 to T8, the switching elements 13 and 14, the control terminals T3 and T4, the QN-off driver circuits 16 and 17, and the switching elements 18 and 19.

The control terminals T1 and T2, the driver circuits 11 and 12, the input/output terminals T5 to T7, the switching elements 13 and 14, the control terminals T3 and T4, the QN-off driver circuits 16 and 17, and the switching elements 18 and 19 are the same as those shown in FIG. 1 described in the first embodiment.

The input/output terminal T8 is either an input terminal or an output terminal. The input/output terminal T8 is coupled to the node N3. A voltage GND is a DC current to be applied to the input/output terminal T8. The voltage GND is applied to the node N3. The voltage GND is a voltage lower than the voltage VSW. The voltage GND is, for example, a ground voltage.

The external capacitor 15 is coupled between the input/output terminal T6 and the input/output terminal T8.

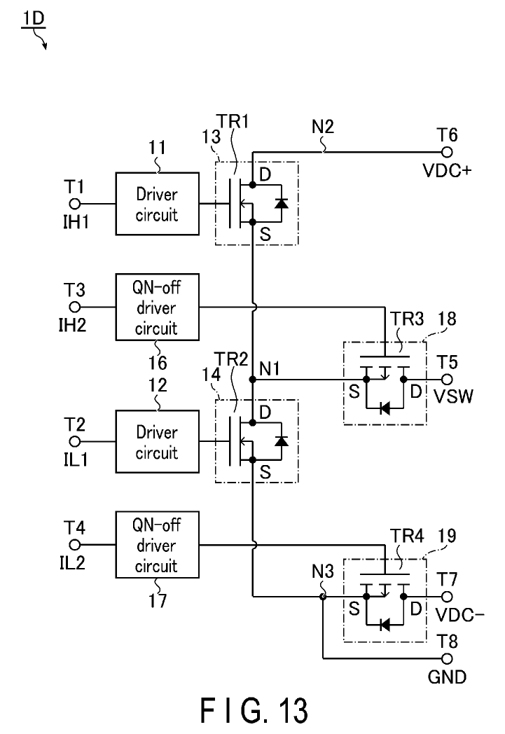

FIG. 13 is a circuit diagram showing an example of a configuration of each switching element in the semiconductor device 1D.

As shown in FIG. 13, the switching element 13 is the transistor TR1. The switching element 14 is the transistor TR2. The switching element 18 is the transistor TR3. The switching element 19 is the transistor TR4. The transistors TR1 to TR4 are the same as those shown in FIG. 2 described in the first embodiment.

### 5.2 Structure of Semiconductor Device

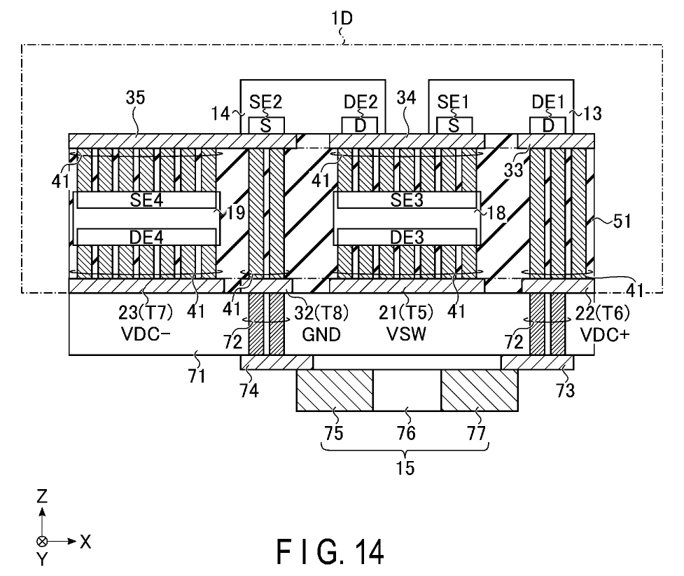

A structure of the semiconductor device 1D will be described with reference to FIG. 14. FIG. 14 is a cross-sectional view showing an example of the cross-sectional structure of the semiconductor device 1D. FIG. 14 is a cross-sectional view along the XZ plane including interconnect layers 21 to 23 and 32 to 35, the switching elements 13, 14, 18, and 19, the plurality of vias 41, and the first substrate 51.

As shown in FIG. 14, the first substrate 51 includes the interconnect layers 21 to 23 and 32 to 35, the switching elements 18 and 19, and the plurality of vias 41. Furthermore, although not shown in FIG. 14, the first substrate 51 includes the interconnects 61 to 64, the driver circuits 11 and 12, and the QN-off driver circuits 16 and 17.

The interconnect layers 21 to 23 and 32 are provided inside the first substrate 51 and are in contact with the back surface of the first substrate 51. The interconnect layers 21 to 23 and 32 are arranged apart from each other in the X direction. The interconnect layers 21, 23, and 32 are arranged in the X direction in order of the interconnect layer 23, the interconnect layer 32, the interconnect layer 21, and the interconnect layer 22. The interconnect layer 32 corresponds to the input/output terminal T8. Hereinafter, the interconnect layer 32 will also be referred to as the “input/output terminal T8”. The voltage GND is applied to the interconnect layer 32. The interconnect layers 21 to 23 and 32 are provided in the same layer.

The switching element 18 is provided above the interconnect layer 21.

The source electrode SE3 and the gate electrode GE3 (not shown) are provided inside the switching element 18 and are in contact with the front surface of the switching element 18, as with the first embodiment. The drain electrode DE3 is provided inside the switching element 18 and is in contact with the back surface of the switching element 18, as with the first embodiment. The drain electrode DE3 of the switching element 18 is coupled to the interconnect layer 21 via the plurality of vias 41.

The switching element 19 is provided above the interconnect layer 23.

The source electrode SE4 and the gate electrode GE4 (not shown) are provided inside the switching element 19 and are in contact with the front surface of the switching element 19, as with the first embodiment. The drain electrode DE4 is provided inside the switching element 19 and is in contact with the back surface of the switching element 19, as with the first embodiment. The drain electrode DE4 of the switching element 19 is coupled to the interconnect layer 23 via the plurality of vias 41.

The interconnect layer 33 is provided above the interconnect layer 22. The interconnect layer 33 is coupled to the interconnect layer 22 via the plurality of vias 41.

The interconnect layer 34 is provided above the switching element 18. The interconnect layer 34 is coupled to the source electrode SE3 of the switching element 18 via the plurality of vias 41. The interconnect layer 34 corresponds to the node N1. Hereinafter, the interconnect layer 34 will also be referred to as the “node N1”.

The interconnect layer 35 is provided above the interconnect layer 32 and the switching element 19. The interconnect layer 35 is coupled to the interconnect layer 32 via the plurality of vias 41. The interconnect layer 35 is coupled to the source electrode SE4 of the switching element 19 via the plurality of vias 41. The interconnect layer 35 corresponds to the node N3. Hereinafter, the interconnect layer 35 will also be referred to as the “node N3”.

The interconnect layers 33 to 35 are provided inside the first substrate 51 and are in contact with the front surface of the first substrate 51. The interconnect layers 33 to 35 are provided in the same layer.

The switching element 13 is provided on the front surfaces of the interconnect layers 33 and 34 and the front surface of the first substrate 51.

The drain electrode DE1, the source electrode SE1, and the gate electrode GE1 (not shown) are provided inside the switching element 13 and are in contact with the back surface of the switching element 13, as with the first embodiment. The drain electrode DE1 of the switching element 13 is in contact with the interconnect layer 33. That is, the drain electrode DE1 of the switching element 13 is coupled to the interconnect layer 33. The source electrode SE1 of the switching element 13 is in contact with the interconnect layer 34. That is, the source electrode SE1 of the switching element 13 is coupled to the interconnect layer 34.

The switching element 14 is provided on the front surfaces of the interconnect layers 34 and 35 and the front surface of the first substrate 51.

The drain electrode DE2, the source electrode SE2, and the gate electrode GE2 (not shown) are provided inside the switching element 14 and are in contact with the back surface of the switching element 14, as with the first embodiment. The drain electrode DE2 of the switching element 14 is in contact with the interconnect layer 34. That is, the drain electrode DE2 of the switching element 14 is coupled to the interconnect layer 34. The source electrode SE2 of the switching element 14 is in contact with the interconnect layer 35. That is, the source electrode SE2 of the switching element 14 is coupled to the interconnect layer 35.

A second substrate 71 is provided on the back surfaces of the interconnect layers 21 to 23 and 32, and the back surface of the first substrate 51.

Interconnect layers 73 and 74 are provided on the back surface of the second substrate 71. The interconnect layer 73 is coupled to the interconnect layer 22 via a plurality of vias 72 each penetrating the second substrate 71. The interconnect layer 74 is coupled to the interconnect layer 32 via a plurality of vias 72 each penetrating the second substrate 71.

The capacitor 15 is provided on the back surfaces of the interconnect layers 73 and 74. The capacitor 15 includes an interconnect layer 75, a dielectric layer 76, and an interconnect layer 77. The dielectric layer 76 is arranged between the interconnect layer 75 and the interconnect layer 77 in the X direction. The interconnect layer 75 is provided on the back surface of the interconnect layer 74. The interconnect layer 77 is provided on the back surface of the interconnect layer 73.

A set of the semiconductor device 1D, the second substrate 71, the plurality of vias 72, the interconnect layers 73 and 74, and the capacitor 15 is, for example, a power supply module.

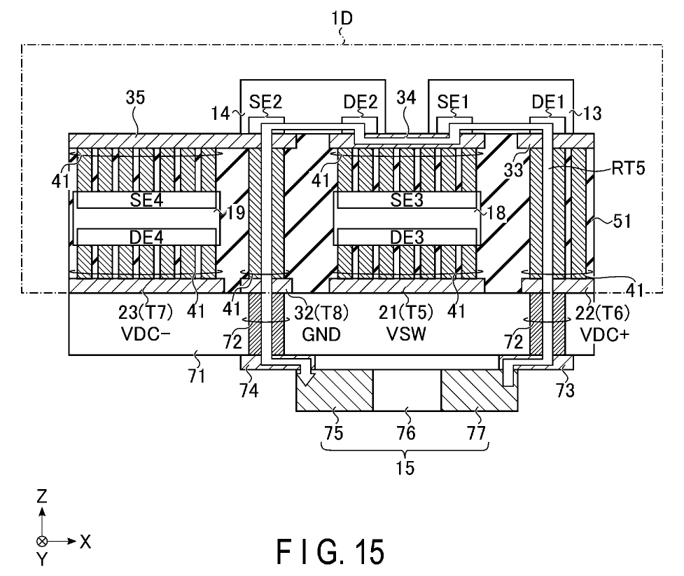

FIG. 15 is a diagram showing a high-frequency current path of a power supply module including the semiconductor device 1D.

As shown in FIG. 15, a high-frequency current path RT5 of the power supply module including the semiconductor device 1D is a path starting from the interconnect layer 77, passing through the interconnect layer 73, the interconnect layer 22, the interconnect layer 33, the drain electrode DE1, the source electrode SE1, the interconnect layer 34, the drain electrode DE2, the source electrode SE2, the interconnect layer 32, and the interconnect layer 74, and reaching the interconnect layer 75.

The semiconductor device 1D according to the present embodiment has a circuit configuration shown in FIG. 12. The capacitor 15 is arranged outside the semiconductor device 1D. Elements included in the high-frequency current path RT5 are, as with the first embodiment, the switching elements 13 and 14 and the capacitor 15. Accordingly, the semiconductor device 1D according to the present embodiment can reduce the parasitic components in the high-frequency current path as with the first embodiment.

Furthermore, as shown in FIG. 14, the capacitor 15 is arranged outside the semiconductor device 1D. For this reason, the efficiency of heat dissipation from the front surfaces of the switching elements 13 and 14 can be improved. Therefore, the semiconductor device 1D according to the present embodiment can realize an increase in efficiency of the device.

Furthermore, as shown in FIG. 14, in the semiconductor device 1D according to the present embodiment, the switching elements 13 and 14 are arranged in positions overlapping the switching element 18 in the Z direction. For this reason, the length in the X direction of the interconnect layers 33 and 34 can be made relatively short. Therefore, the semiconductor device 1D according to the present embodiment can realize down-sizing of the device.

### 6. Modifications, etc.

As described above, a semiconductor device (1) according to an embodiment includes a first terminal (T5) to which a first voltage (VSW) is applied, a second terminal (T6) to which a second voltage (VDC+) higher than the first voltage is applied, a third terminal (T7) to which a third voltage (VDC-) lower than the first voltage is applied, a first node (N1), a second node (N3), a fourth terminal (T8) which is coupled to the second node and to which a fourth voltage (GND) lower than the first voltage is applied, a first switch (13), a second switch (14), a third switch (18), and a fourth switch (19). The first switch (13) is a normally-on type switch coupled between the second terminal (T6) and the first node (N1). The second switch (14) is a normally-on type switch coupled between the first node (N1) and the second node (N3). The third switch (18) is a normally-off type switch coupled between the first node (N1) and the first terminal (T5). The fourth switch (19) is a normally-off type switch coupled between the second node (N3) and the third terminal (T7).

The embodiments are not limited to those described in the above, and various modifications can be made.

### 6.1 Modification of Third Embodiment

A semiconductor device according to a modification of the third embodiment will be described. A semiconductor device 1E according to a modification of the third embodiment differs from that of the third embodiment in terms of the arrangement of the switching elements 13, 14, and 19 and the interconnect layers 21 to 23. A circuit configuration of the semiconductor device 1E according to the modification of the third embodiment is the same as that of the third embodiment. The following description will concentrate on the features different from the third embodiment.

### 6.1.1 Structure of Semiconductor Device

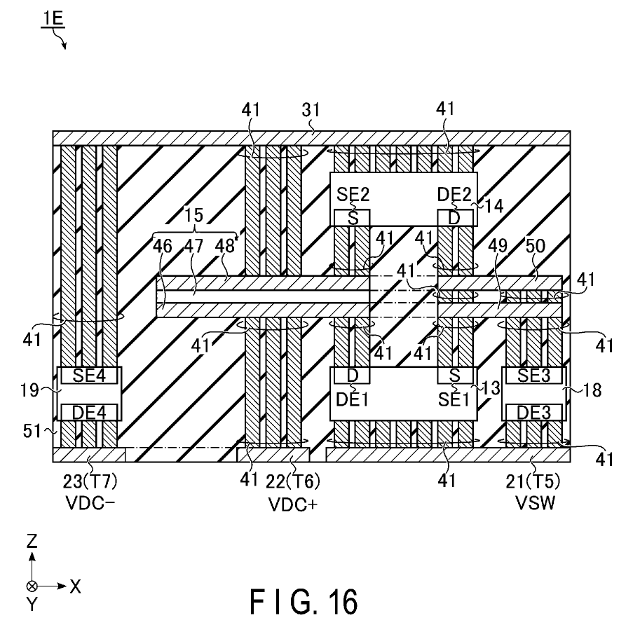

A structure of the semiconductor device 1E will be described with reference to FIG. 16. FIG. 16 is a cross-sectional view showing an example of the cross-sectional structure of the semiconductor device 1E. FIG. 16 is a cross-sectional view along the XZ plane including the interconnect layers 21 to 23, 31, 49, and 50, the switching elements 13, 14, 18, and 19, the capacitor 15, the plurality of vias 41, and the first substrate 51.

As shown in FIG. 16, the interconnect layers 21 to 23 are provided inside the first substrate 51 and are in contact with the back surface of the first substrate 51. The interconnect layers 21 to 23 are arranged apart from each other in the X direction. The interconnect layer 22 is arranged between the interconnect layer 21 and the interconnect layer 23 in the X direction. The interconnect layers 21 to 23 are provided in the same layer.

The switching elements 13 and 18 are provided above the interconnect layer 21.

The drain electrode DE1, the source electrode SE1, and the gate electrode GE1 (not shown) are provided inside the switching element 13 and are in contact with the front surface of the switching element 13, as with the first embodiment. The back surface of the switching element 13 is coupled to the interconnect layer 21 via the plurality of vias 41.

The source electrode SE3 and the gate electrode GE3 (not shown) are provided inside the switching element 18 and are in contact with the front surface of the switching element 18, as with the first embodiment. The drain electrode DE3 is provided inside the switching element 18 and is in contact with the back surface of the switching element 18, as with the first embodiment. The drain electrode DE3 of the switching element 18 is coupled to the interconnect layer 21 via the plurality of vias 41.

The switching element 19 is provided above the interconnect layer 23.

The source electrode SE4 and the gate electrode GE4 (not shown) are provided inside the switching element 19 and are in contact with the front surface of the switching element 19, as with the first embodiment. The drain electrode DE4 is provided inside the switching element 19 and is in contact with the back surface of the switching element 19, as with the first embodiment. The drain electrode DE4 of the switching element 19 is coupled to the interconnect layer 23 via the plurality of vias 41.

The interconnect layer 49 is provided above the switching elements 18 and 13. The interconnect layer 49 is coupled to the source electrode SE3 of the switching element 18 via the plurality of vias 41. The interconnect layer 49 is coupled to the source electrode SE1 of the switching element 13 via the plurality of vias 41. The interconnect layer 49 corresponds to the node N1. Hereinafter, the interconnect layer 49 will also be referred to as the “node N1”.

The interconnect layer 50 is provided above the interconnect layer 49. The interconnect layer 50 is coupled to the interconnect layer 49 via the plurality of vias 41. The plurality of vias 41 between the interconnect layer 50 and the interconnect layer 49 are respectively arranged in positions corresponding to, for example, the plurality of vias 41 between the interconnect layer 49 and the source electrode SE3 of the switching element 18, and the plurality of vias 41 between the interconnect layer 49 and the source electrode SE1 of the switching element 13.

The capacitor 15 is provided above the interconnect layer 22 and above the switching element 13. The capacitor 15 includes the interconnect layer 46, the dielectric layer 47, and the interconnect layer 48. The dielectric layer 47 is provided on the front surface of the interconnect layer 46. The interconnect layer 48 is provided on a front surface of the dielectric layer 47. The interconnect layer 46 is coupled to the drain electrode DE1 of the switching element 13 via the plurality of vias 41. The interconnect layers 46 and 49 are provided in the same layer. The interconnect layers 48 and 50 are provided in the same layer. The interconnect layer 48 is one electrode of the capacitor 15, and corresponds to the node N3. Hereinafter, the interconnect layer 48 will also be referred to as the “node N3”.

The switching element 14 is provided above the interconnect layers 50 and 48. In other words, the switching element 14 is provided above the interconnect layer 49 and the capacitor 15.

The drain electrode DE2, the source electrode SE2, and the gate electrode GE2 (not shown) are provided inside the switching element 14 and are in contact with the back surface of the switching element 14, as with the first embodiment. The drain electrode DE2 of the switching element 14 is coupled to the interconnect layer 50 via the plurality of vias 41. The plurality of vias 41 between the drain electrode DE2 of the switching element 14 and the interconnect layer 50 are respectively arranged in positions corresponding to, for example, the plurality of vias 41 between the interconnect layer 49 and the source electrode SE1 of the switching element 13. The source electrode SE2 of the switching element 14 is coupled to the interconnect layer 48 via the plurality of vias 41. The plurality of vias 41 between the source electrode SE2 of the switching element 14 and the interconnect layer 48 are arranged in positions corresponding to, for example, the plurality of vias 41 between the interconnect layer 46 and the drain electrode DE1 of the switching element 13.

The interconnect layer 31 is provided above the interconnect layers 50 and 48, and above the switching elements 14 and 19. The interconnect layer 31 is provided inside the first substrate 51 and is in contact with the front surface of the first substrate 51. The front surface of the interconnect layer 48 is coupled to the interconnect layer 31 via the plurality of vias 41. The front surface of the switching element 14 is coupled to the interconnect layer 31 via the plurality of vias 41. The front surface of the switching element 19 is coupled to the interconnect layer 31 via the plurality of vias 41.

The semiconductor device 1E according to the modification has the structure described above. Accordingly, the semiconductor device 1E according to the present modification produces advantageous effects similar to those of the third embodiment.

### 6.2 Modification of Fourth Embodiment

A semiconductor device according to a modification of the fourth embodiment will be described. A semiconductor device 1F according to the modification of the fourth embodiment differs from that of the modification of the third embodiment in that the interconnect layer 31 is eliminated, that the interconnect layer 48 is longer than the interconnect layer 46 in the X direction, and that the switching element 14 is provided on the front surface of the first substrate 51. A circuit configuration of the semiconductor device 1F according to the modification of the fourth embodiment is the same as the modification of the third embodiment. The following description will concentrate on the features different from the modification of the third embodiment.

### 6.2.1 Structure of Semiconductor Device

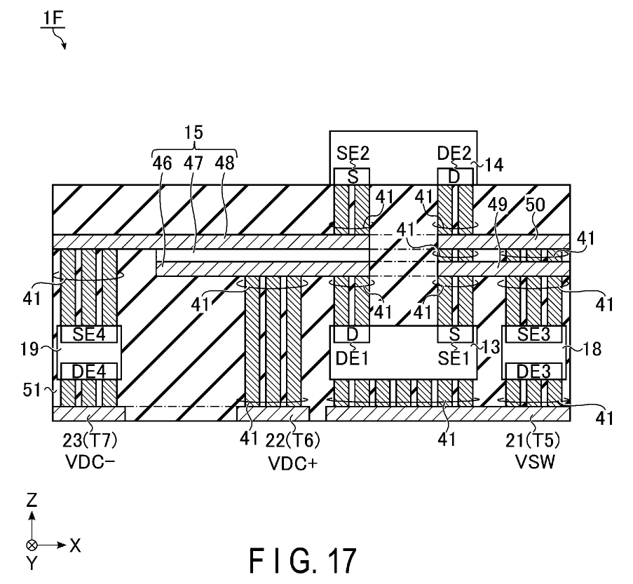

A structure of the semiconductor device 1F will be described with reference to FIG. 17. FIG. 17 is a cross-sectional view showing an example of the cross-sectional structure of the semiconductor device 1F. FIG. 17 is a cross-sectional view along the XZ plane including the interconnect layers 21 to 23, the switching elements 13, 14, 18, and 19, the capacitor 15, the plurality of vias 41, and the first substrate 51.

As shown in FIG. 17, the interconnect layer 48 is longer than the interconnect layer 46 in the X direction. In other words, the interconnect layer 48 has a portion (“extending portion”) that extends in the X direction further than the interconnect layer 46. The extending portion of the interconnect layer 48 is coupled to the front surface of the switching element 19 via the plurality of vias 41.

The switching element 14 is provided on the front surface of the first substrate 51. The switching element 14 is flip-chip mounted on the front surface of the first substrate 51.

The drain electrode DE2, the source electrode SE2, and the gate electrode GE2 (not shown) are provided inside the switching element 14 and are in contact with the back surface of the switching element 14, as with the first embodiment. The drain electrode DE2 of the switching element 14 is coupled to the interconnect layer 50 via the plurality of vias 41. The plurality of vias 41 between the drain electrode DE2 of the switching element 14 and the interconnect layer 50 are respectively arranged in positions corresponding to, for example, the plurality of vias 41 between the interconnect layer 49 and the source electrode SE1 of the switching element 13. The source electrode SE2 of the switching element 14 is coupled to the interconnect layer 48 via the plurality of vias 41. The plurality of vias 41 between the source electrode SE2 of the switching element 14 and the interconnect layer 48 are respectively arranged in positions corresponding to, for example, the plurality of vias 41 between the interconnect layer 46 and the drain electrode DE1 of the switching element 13.

The semiconductor device 1F according to the modification has the structure described above. Accordingly, the semiconductor device 1F according to the present modification produces advantageous effects similar to those of the fourth embodiment.

Throughout the specification, the expression "coupling" refers to electrical coupling and does not exclude, for example, interposition of another element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first terminal to which a first voltage is applied;
a second terminal to which a second voltage higher than the first voltage is applied;
a third terminal to which a third voltage lower than the first voltage is applied;
a first node;
a second node;
a fourth terminal which is coupled to the second node and to which a fourth voltage lower than the first voltage is applied;
a normally-on first switch coupled between the second terminal and the first node;
a normally-on second switch coupled between the first node and the second node;
a normally-off third switch coupled between the first node and the first terminal; and
a normally-off fourth switch coupled between the second node and the third terminal.

2. The device according to claim 1, wherein
an external capacitor is coupled between the second terminal and the fourth terminal.

3. The device according to claim 1, further comprising:
a first substrate,
wherein the first substrate includes the first to fourth terminals, the first and second nodes, and the third and fourth switches.

4. The device according to claim 3, wherein
the first to fourth terminals are in contact with a back surface of the first substrate;
the third switch is provided above the first terminal;
the fourth switch is provided above the third terminal;
the first node is provided above the third switch;
the second node is provided above the fourth terminal and the fourth switch; and
the first switch and the second switch are provided on a front surface of the first substrate.

5. A semiconductor device comprising:
a first terminal to which a first voltage is applied;
a second terminal to which a second voltage higher than the first voltage is applied;
a third terminal to which a third voltage lower than the first voltage is applied;
a first node;
a second node;
a normally-on first switch coupled between the second terminal and the first node;
a normally-on second switch coupled between the first node and the second node;
a normally-off third switch coupled between the first node and the first terminal;
a normally-off fourth switch coupled between the second node and the third terminal; and
a capacitor coupled between the second terminal and the second node.

6. The device according to claim 5, further comprising:
a first substrate,
wherein the first substrate includes the first to third terminals, the first and second nodes, and the first to fourth switches.

7. The device according to claim 6, wherein
the first to third terminals are in contact with a back surface of the first substrate,
the first switch and the third switch are provided above the first terminal,
the second switch and the fourth switch are provided above the third terminal,
the first node is provided above the first to third switches,
the second node is provided above the second switch and the fourth switch, and
the capacitor is provided on a front surface of the first substrate.

8. The device according to claim 5, wherein
each of the first to third terminals is a lead frame.

9. The device according to claim 8, wherein
the first switch and the third switch are provided on a front surface of the first terminal,
the second switch and the fourth switch are provided on a front surface of the third terminal,
the first node is configured to couple the first switch and the third switch, and couple the second switch and the third switch,
the second node is configured to couple the second switch and the fourth switch, and
the capacitor is provided above the first to fourth switches.

10. The device according to claim 9, further comprising:
a first interconnect layer provided on a front surface of the second terminal; and
a second interconnect layer provided on the fourth switch,
wherein both ends of the capacitor are in contact with the first interconnect layer and the second interconnect layer, respectively.

11. The device according to claim 5, further comprising:
a first substrate,
wherein the first substrate includes the first to third terminals, the first and second nodes, the first to fourth switches, and the capacitor.

12. The device according to claim 11, wherein
the first to third terminals are in contact with a back surface of the first substrate,
the third switch is provided above the first terminal,
the second switch and the fourth switch are provided above the third terminal,
the first node is provided above the second switch and the third switch,
the capacitor is provided above the second switch and the fourth switch,
one electrode of the capacitor corresponds to the second node, and
the first switch is provided above the first node and the capacitor.

13. The device according to claim 11, wherein
the first to third terminals are in contact with a back surface of the first substrate,
the first switch and the third switch are provided above the first terminal,
the fourth switch is provided above the third terminal,
the first node is provided above the first switch and the third switch,
the capacitor is provided above the first switch and the second terminal,
one electrode of the capacitor corresponds to the second node, and
the second switch is provided above the first node and the capacitor.

14. The device according to claim 5, further comprising:
a first substrate,
wherein the first substrate includes the first to third terminals, the first and second nodes, the second to fourth switches, and the capacitor.

15. The device according to claim 14, wherein
the first to third terminals are in contact with a back surface of the first substrate,
the third switch is provided above the first terminal,
the second switch and the fourth switch are provided above the third terminal,
the first node is provided above the second switch and the third switch,
the capacitor is provided above the second switch and the fourth switch,
one electrode of the capacitor corresponds to the second node, and
the first switch is provided on a front surface of the first substrate.

16. The device according to claim 14, wherein
the first to third terminals are in contact with a back surface of the first substrate,
the first switch and the third switch are provided above the first terminal,
the fourth switch is provided above the third terminal,
the first node is provided above the first switch and the third switch,
the capacitor is provided above the first switch and the second terminal,
one electrode of the capacitor corresponds to the second node, and
the second switch is provided on a front surface of the first substrate.

17. The device according to claim 1, wherein
in a case where a power supply is in an unstable state, the third switch and the fourth switch are turned off, and
in a case where the power supply is in a stable state, the third switch and the fourth switch are turned on, and the first switch and the second switch are alternately turned on or off.

18. The device according to claim 1, wherein
the first switch is a first transistor,
a first electrode of the first transistor is coupled to the second terminal, and a second electrode of the first transistor is coupled to the first node,
the second switch is a second transistor,
a third electrode of the second transistor is coupled to the first node, and a fourth electrode of the second transistor is coupled to the second node,
the third switch is a third transistor,
a fifth electrode of the third transistor is coupled to the first node, and a sixth electrode of the third transistor is coupled to the first terminal,
the fourth switch is a fourth transistor, and
a seventh electrode of the fourth transistor is coupled to the second node, and an eighth electrode of the fourth transistor is coupled to the third terminal.

19. The device according to claim 1, wherein
the first switch and the second switch each include at last one of an n-channel metal-oxide-semiconductor field-effect transistor (MOSFET), a p-channel MOSFET, a gallium nitride (GaN) transistor, a silicon carbide (SiC) transistor, an insulated-gate bipolar transistor (IGBT), or a junction field-effect transistor (JFET).

20. The device according to claim 1, wherein
the third switch and the fourth switch each include at least one of an n-channel MOSFET or a p-channel MOSFET.
